(19) United States
(12) Patent Application Publication
(10) Pub. No.: US 2016/0240366 A1
(43) Pub. Date: Aug. 18, 2016

(54) Processing of Semiconductor Devices

(71) Applicant: INFINEON TECHNOLOGIES AG, Neubiberg (DE)

(72) Inventors: Manfred Engelhardt, Villach-Landskron (AT); Hannes Eder, Villach-Landskron (AT)

(21) Appl. No.: 14/624,205

(22) Filed: Feb. 17, 2015

(51) Int. Cl. H01L 21/02; H01L 21/324; H01L 21/66; H01L 21/3065

(52) U.S. Cl. CPC H01L 21/02019; H01L 21/02013; H01L 21/3065; H01L 21/3247; H01L 22/12

(57) ABSTRACT

A method of thinning a wafer includes thinning the wafer using a grinding process. The wafer, after the grinding processing, has a first non-uniformity in thickness. The thinned wafer is etched using a plasma process. The wafer after the etching processing has a second non-uniformity in thickness. The second non-uniformity is less than the first non-uniformity.

### TECHNICAL FIELD

The present invention relates generally to semiconductor fabrication, and, in particular embodiments, to processing of semiconductor devices.

### BACKGROUND

Semiconductor devices are used in many electronic and other applications. Semiconductor devices may comprise integrated circuits that are formed on semiconductor wafers. Alternatively, semiconductor devices may be formed as monolithic devices, e.g., discrete devices. Semiconductor devices are formed on semiconductor wafers by depositing many types of thin films of material over the semiconductor wafers, patterning the thin films of material, doping selective regions of the semiconductor wafers, etc.

In a conventional semiconductor fabrication process, a large number of semiconductor devices are fabricated in a single wafer. After completion of device level and interconnect level fabrication processes, the semiconductor devices on the wafer are separated. However, prior to separation or singulation, the wafers are thinned to reduce the thickness of the substrate.

One of the challenges during fabrication relates to process variations. Every process step during the fabrication introduces some variation. For example, identically designed devices on different parts of the same chip may have differently, adjacent identically designed chips on a wafer may behave differently, identically designed chips on different wafers may behave differently, or chips on different batches of wafers may behave differently. Process variation may result in yield loss because the performance of individual devices or the whole chip becomes out of bound, and can therefore dramatically increase the cost of the product. One of the challenges of semiconductor fabrication relates to improvement or reduction in process variation while reducing process margins.

### SUMMARY

In accordance with an embodiment of the present invention, a method of thinning a wafer. The method comprises thinning a wafer using a grinding process. The wafer, after the grinding processing, has a first non-uniformity in thickness. Using a plasma process, the thinned wafer is etched. The wafer, after the etching processing, has a second non-uniformity in thickness. The second non-uniformity is less than the first non-uniformity.

In accordance with an alternative embodiment of the present invention, a method of etching comprises mounting a substrate in a process chamber. The substrate is mounted over a heating unit comprising a plurality of heating elements disposed in a plane parallel to the substrate. Each of the plurality of heating elements is heated. The level of heating of each of the plurality of heating elements is varied in a non-radial pattern for producing a non-radial heat distribution emanating from the plurality of heating elements. The substrate is etched in the process chamber after the heating.

In accordance with an alternative embodiment of the present invention, a method of thinning a wafer comprises providing a wafer having a first non-radial non-uniformity in thickness. The wafer is etched using a plasma process. The wafer, after the etching process, has a second non-radial non-uniformity in thickness. The second non-radial non-uniformity is less than the first non-radial uniformity. The heating pattern for heating an exposed major surface of the wafer is computed to reduce the first non-radial non-uniformity to the second non-radial non-uniformity before the etching.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a semiconductor device during fabrication in accordance with an embodiment of the present invention;

FIG. 2A illustrates a semiconductor device during fabrication during a thinning process in accordance with embodiments of the present invention;

FIG. 2B illustrates a semiconductor device during fabrication after mounting the substrate over a frame in accordance with an alternative embodiment of the present invention;

FIG. 3A illustrates a semiconductor device during fabrication after thinning the substrate mounted over a carrier in accordance with embodiments of the present invention;

FIGS. 3B-3C illustrates a magnified portion of the back side surface after the mechanical thinning process illustrating the rough surface, wherein FIGS. 3B and 3C illustrate a similar radial location and show differences due to non-radial component of the grinding process, and wherein FIG. 3D illustrates a different radial location and may include both radial and non-radial components;

FIG. 4A illustrates processing the wafer in a plasma chamber for a subsequent plasma etching process in accordance with embodiments of the present invention;

FIG. 4B illustrates a top sectional view of the heating unit within the electrostatic chuck in accordance with an embodiment of the present invention;

FIG. 4C illustrates a top sectional view of the plurality of localized/segmented heating units in accordance with an embodiment of the present invention;

FIG. 4D illustrates a plurality of localized/segmented heating units in accordance with an embodiment of the present invention;

FIG. 5A illustrates the wafer at the end of the plasma etching process in accordance with embodiments of the present invention;

FIG. 5B illustrates a process flow for forming a semiconductor device as described above in accordance with embodiments of the present invention;

FIG. 6 illustrates a plasma etching process using an alternative design for the localized temperature control units in accordance with an embodiment of the present invention;

FIG. 7A illustrates a top sectional view of a heating unit comprising radial and non-radial heating elements in accordance with an embodiment of the present invention;

FIG. 7B illustrates a top sectional view of a heating unit comprising non-radial heating elements in accordance with an embodiment of the present invention; and

FIG. 8 illustrates a deposition system in accordance with an embodiment of the present invention.

### DETAILED DESCRIPTION OF ILLUSTRATIVE EMBODIMENTS

Wafers are typically thinned from the back side after completion of all front side processing. Wafer thinning reduces resistance for current flow, particularly during ON state referred as ON resistance, and improves heat extraction from the die during operation.

Power applications with vertical devices have more stringent requirements because of the strong dependence of ON resistance on the thickness of the final die. Therefore, technology progress is driven by a decrease in substrate thickness. However, one of the challenges relating to thinning involves reducing or minimizing variations in thickness across the wafer. Large variations in thickness of the die during thinning result in variation in ON resistance as well as heat extraction capacity, and therefore a variation in the performance of the die.

Conventional methods used for substrate thinning use a combination of mechanical grinding and spin etching. However, large non-uniformities can result during the thinning process.

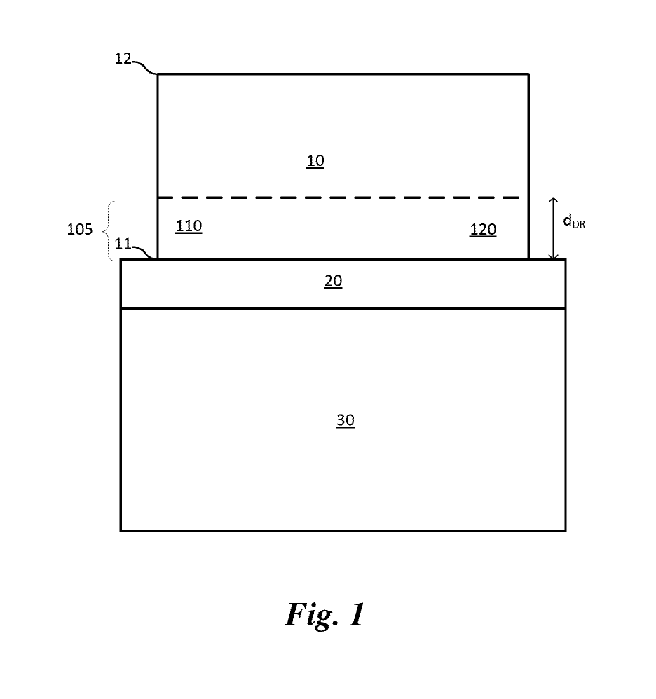

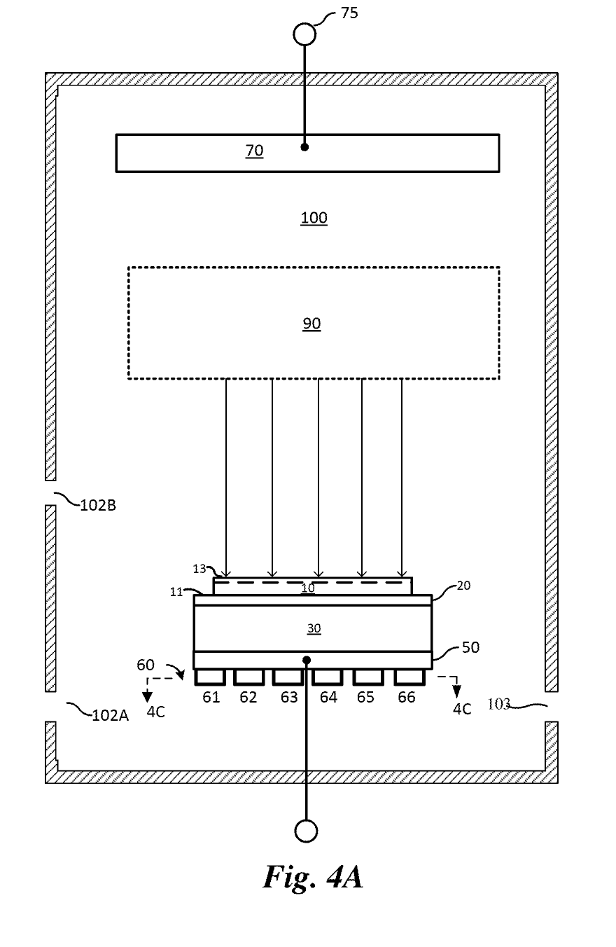

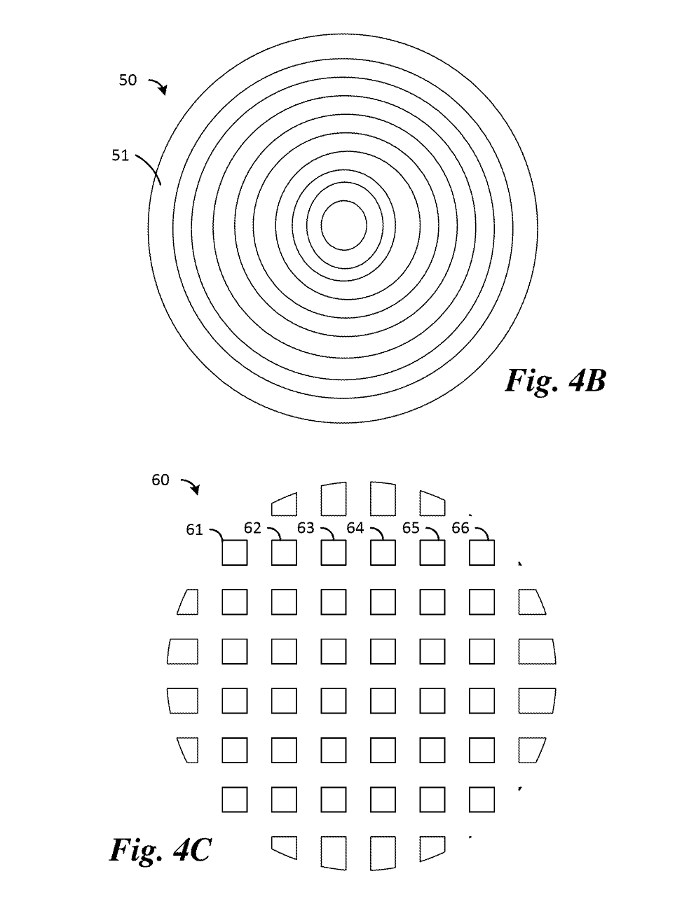

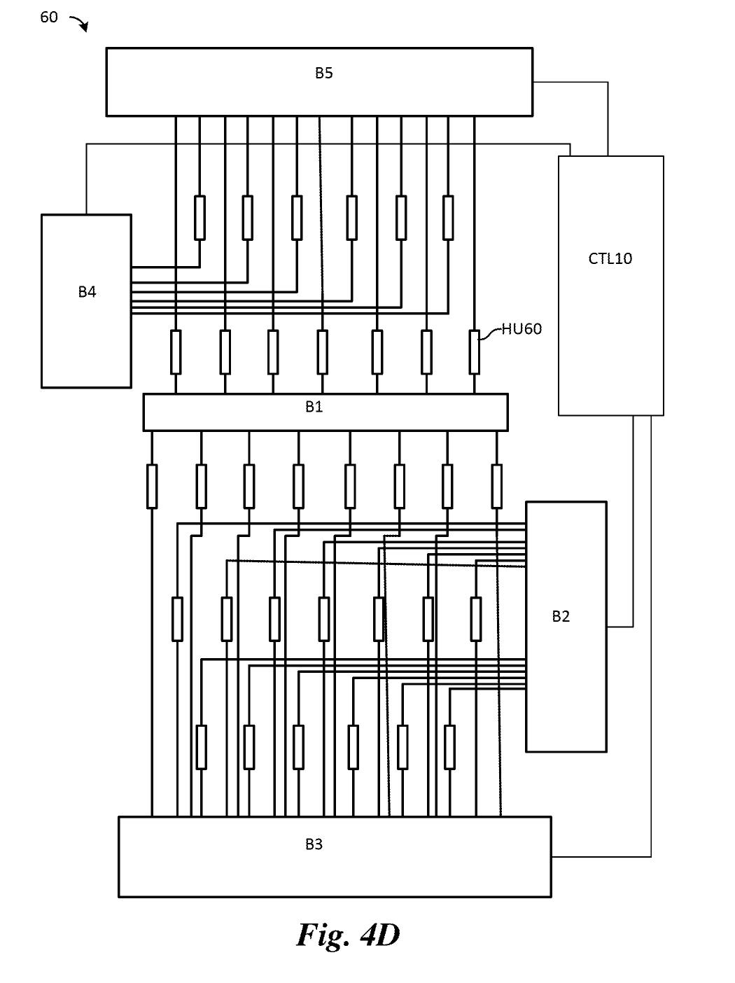

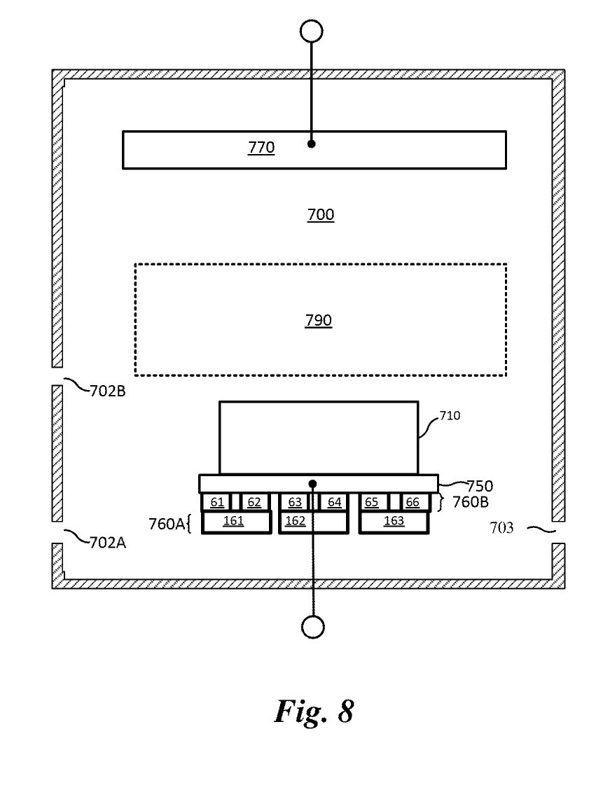

Embodiments of the present invention use a plasma based wafer substrate thinning process to address both radial and non-radial non-uniformities, which is otherwise not achievable using conventional thinning techniques. Accordingly, an embodiment process will be described using FIGS. 1-5. Additional methods will be described using FIG. 8. Structural embodiments of the present invention will be described using FIGS. 4, 6, 7, 8.

FIG. 1 illustrates a semiconductor device during fabrication in accordance with an embodiment of the present invention.

Referring to FIG. 1, a semiconductor substrate 10 after the completion of front end processing and back end processing is illustrated. The semiconductor substrate 10 has a plurality of semiconductor devices, e.g., a first chip 110, a second chip 120, formed within. Each of these chips may be any type of chip. For example, the chip may be a logic chip, a memory chip, an analog chip, and other types of chips. The chip may comprise a plurality of devices such as transistors or diodes forming an integrated circuit or may be a discrete device such as a single transistor or a single diode. In one embodiment, these are power chips and are vertical devices.

In one embodiment, the semiconductor substrate 10 may comprise a semiconductor wafer such as a silicon wafer. In other embodiments, the semiconductor substrate 10 may comprise other semiconductor materials including alloys such as SiGe, SiC or compound semiconductor materials such as GaAs, InP, InAs, GaN, sapphire, silicon on insulation, for example. The semiconductor substrate 10 may include epitaxial layers in one or more embodiments. In some embodiments, the semiconductor substrate 10 may comprise a layer of GaN on silicon, or a layer of other heteroepitaxial material on silicon, or other substrates.

Referring to FIG. 1, device regions 105 including the first chip 110 and the second chip 120 are disposed within the semiconductor substrate 10. The device regions 105 may include doped regions in various embodiments. Further, some portion of the device regions 105 may be formed over the semiconductor substrate 10. The device regions 105 may include the active regions such as channel regions of transistors.

The semiconductor substrate 10 comprises a front side 11 and an opposite back side 12. In various embodiments, the active devices are formed closer to the front side 11 of the semiconductor substrate 10 than the back side 12. The active devices are formed in device regions 105 of the semiconductor substrate 10. Device regions 105 extends over a depth d_{DR}, which depending on the device, is about 5 μm to about 50 μm, and about 10 μm in one embodiment.

In various embodiments, all necessary interconnects, connections, pads etc. for coupling between devices and/or with external circuitry are formed over the front side 11 of the semiconductor substrate 10. Accordingly, a metallization layer is formed over the semiconductor substrate 10. The metallization layer may comprise one or more levels of metallization. Each level of metallization may comprise metal lines or vias embedded within an insulating layer. The metallization layer may comprise metal lines and vias to contact the device regions and also to couple different devices within the chips.

A protective layer, such as a passivation layer, may be formed over the metallization layer before further processing. The protective layer may comprise an oxide, nitride, polyimide, or other suitable materials known to one skilled in the art. The protective layer may comprise a hard mask in one embodiment, and a resist mask in another embodiment. The protective layer helps to protect the metallization layer as well as the device regions during subsequent processing.

After forming the protective layer, the front side 11 of the semiconductor substrate 10 is attached to a carrier 30 using an adhesive component 20. Further, in some embodiments, a primer coating may be applied prior to coating the adhesive component 20. The primer coating is tuned to react with the surface of the semiconductor substrate 10 and convert potentially high surface energy surfaces to lower surface energy surfaces by forming a primer layer. Thus, in this embodiment, the adhesive component 20 interacts only with the primer layer improving the bonding.

In one or more embodiments, the adhesive component 20 may comprise a substrate, e.g., polyvinyl chloride, with the coating of an adhesive layer such as an acrylic resin.

The adhesive component 20 may comprise an organic compound such an epoxy based compound in alternative embodiments. In various embodiments, the adhesive component 20 comprises an acrylic based, not photoactive, organic glue. In one embodiment, the adhesive component 20 comprises acrylamide. In another embodiment, the adhesive component 20 comprises SU-8, which is a negative tone epoxy based photo resist.

In alternative embodiments, the adhesive component 20 may comprise a molding compound. In one embodiment, the adhesive component 20 comprises an imide and/or components such a poly-methyl-methacrylate (PMMA) used in forming a poly-imide.

In another embodiment, the adhesive component 20 comprises components for forming an epoxy-based resin or co-polymer and may include components for a solid-phase epoxy resin and a liquid-phase epoxy resin. Embodiments of the invention also include combinations of different type of adhesive components and non-adhesive components such as combinations of acrylic base organic glue, SU-8, imide, epoxy-based resins etc.

In various embodiments, the adhesive component 20 comprises less than about 1% inorganic material, and about 0.1% to about 1% inorganic material in one embodiment. The absence of inorganic content improves the removal of the adhesive component 20 without leaving residues after plasma etching.

In one or more embodiments, the adhesive component 20 may comprise thermosetting resins, which may be cured by annealing at an elevated temperature. Alternatively, in some embodiments, a low temperature annealing or bake may be performed to cure the adhesive component 20 so that adhesive bonding between the carrier 30 and the adhesive component 20 and between the adhesive component 20 and the semiconductor substrate 10 is formed. Some embodiments may not require any additional heating and may be cured at room temperature or using UV cure.

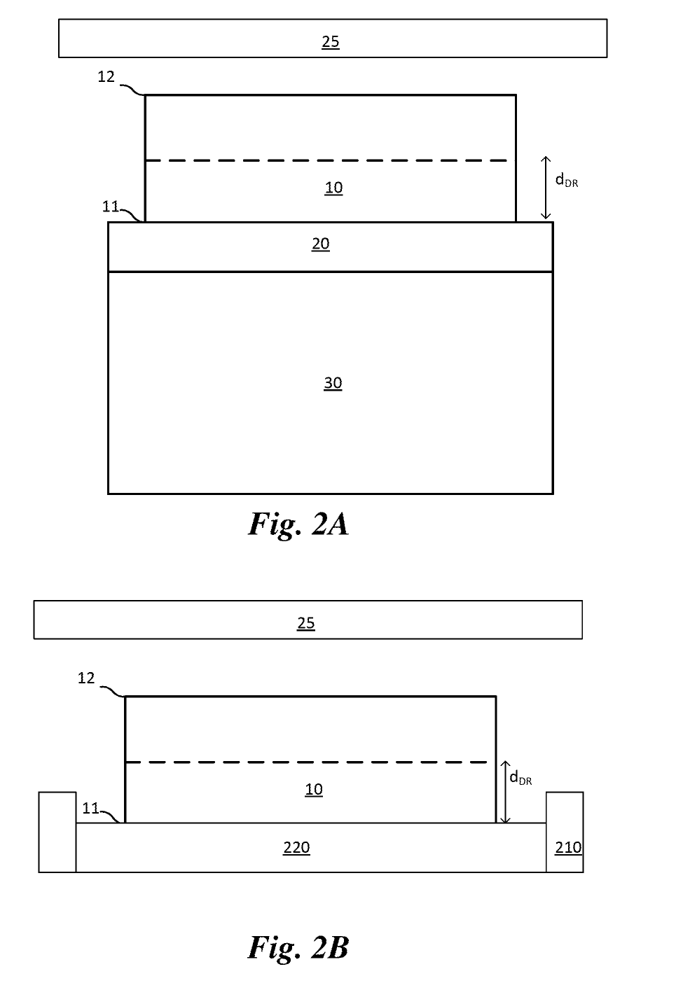

FIG. 2A illustrates a semiconductor device during fabrication during a thinning process in accordance with embodiments of the present invention.

After mounting the semiconductor substrate 10 over the carrier 30 using the adhesive component 20, the semiconductor substrate 10 is subjected to a thinning process. The final depth of the chip formed in the semiconductor substrate 10 will be determined after thinning. The bottom surface of the first chip 110 and the second chip 120 will be exposed after a thinning process.

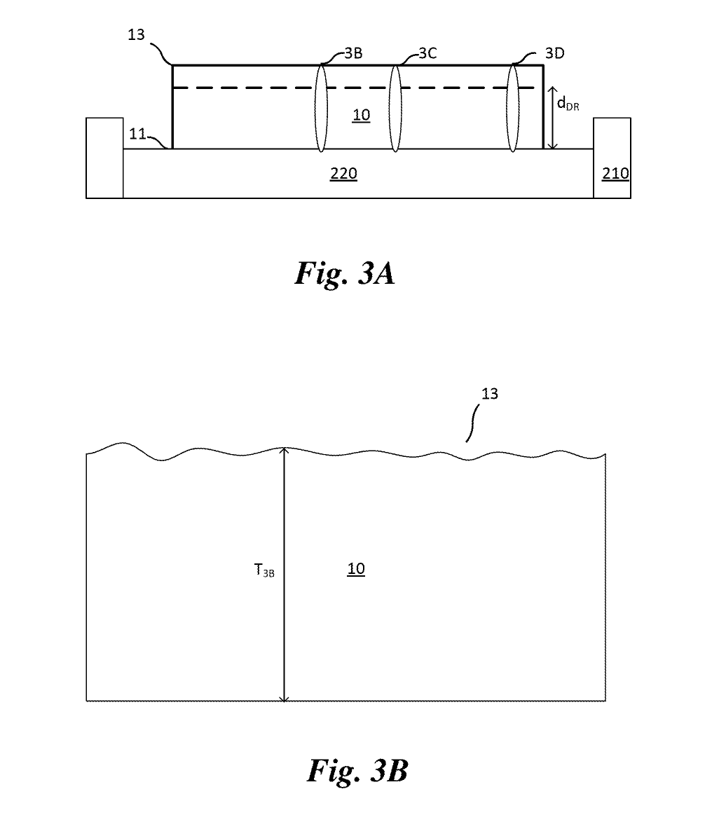

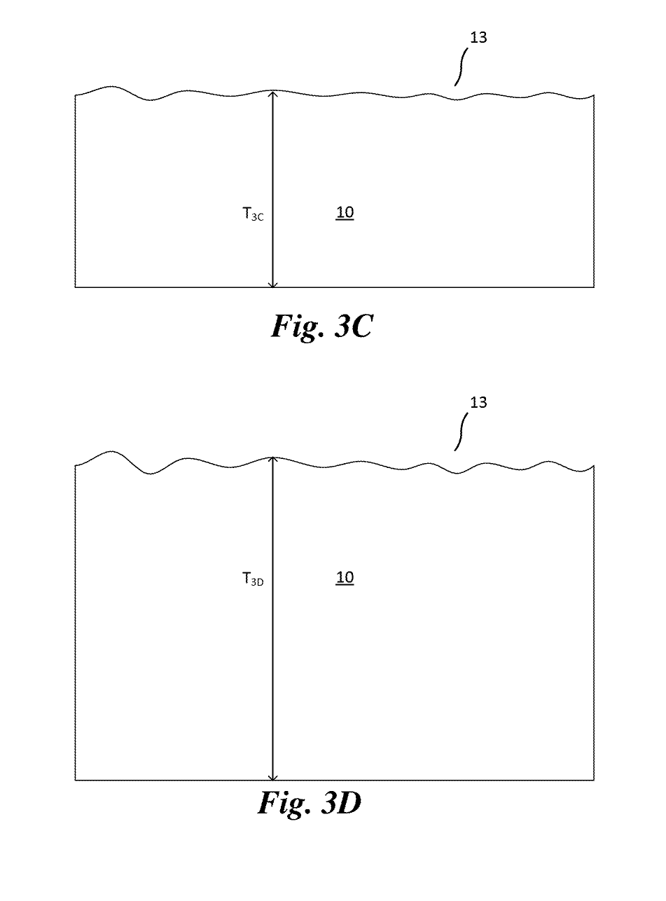

A thinning tool 25, which may be a grinding tool in one embodiment, reduces the thickness of the semiconductor substrate 10. The bottom surface 12 is exposed to a grinding process that thins the substrate 10 exposing a lower surface 13 (see FIG. 3). In another embodiment, the thinning tool may further include a chemical process such as wet etching or plasma etching to thin the semiconductor substrate 10. The thinning process exposes a new back side 13 (see FIG. 3) of the semiconductor substrate 10.

FIG. 2B illustrates a semiconductor device during fabrication after mounting the substrate over a frame in accordance with an alternative embodiment of the present invention.

In an alternative embodiment, instead of the carrier illustrated in FIG. 2A, the substrate 10 may be mounted to a frame 210 comprising an adhesive tape 220. The substrate 10 is attached to the adhesive tape 220 within the outer frame 210.

The frame 210, which is an annular structure, supports the adhesive tape 220 along the outer edges in one or more embodiments. The adhesive tape 220 may be a dicing tape in one embodiment. In another embodiment, the adhesive tape 220 may have a substrate, e.g., polyvinyl chloride, with the coating of an adhesive layer such as an acrylic resin. In one or more embodiments, the frame 210 comprises a supporting material such as a metal or plastic (ceramic) material. In various embodiments, the inside diameter of the frame 210 is greater than the diameter of the substrate 10.

FIG. 3A illustrates a semiconductor device during fabrication after mechanically thinning the substrate mounted over a carrier in accordance with embodiments of the present invention. FIG. 3B illustrates a magnified portion of the back side surface 13 after the mechanical thinning process illustrating the rough surface.

After the grinding process, a new back side surface 13 is exposed. This surface may be a rough surface and is usually smoothed using a plasma thinning process. Further, the thickness of the substrate may vary across the wafer. The variation in thickness may include a radial component and a non-radial component. As an example, a portion of the surface formed after the mechanical grinding process is illustrated in FIGS. 3B-3D at different locations. FIGS. 3B and 3C illustrate a similar radial location and show differences due to non-radial component of the grinding process. FIG. 3D illustrates a different radial location and may include both radial and non-radial components. The thickness of the substrate 10 in the three different locations is referenced as T_{3B} in FIG. 3B, T_{3C} in FIG. 3C, and T_{3D} in FIG. 3D. The faster grinding process may result in larger thickness non-uniformity.

FIG. 4A illustrates processing the wafer in a plasma chamber for a subsequent plasma thinning process in accordance with embodiments of the present invention.

The final step in the thinning process may include a plasma etching process. Conventional plasma etch processes often have an influence on the roughness of the surface exposed to the plasma. However, embodiments of the present invention use the plasma process to reduce both radial and non-radial non-uniformities introduced during the grinding process.

Plasma etch systems may be designed to be either reactive or ionic, and are typically a combination of both. The net etch rate of the plasma etching process may be higher than the individual etch rates obtainable using a reactive wet etching or a physical etching process.

Referring to FIG. 4A, the wafer comprising the substrate 10 is placed within a plasma chamber 100 of a plasma tool and subjected to a plasma process. The plasma etching process is performed in a plasma chamber 100 comprising one or more inlets 102A and 102B and one or more outlets 103. The plasma chemistry is controlled by a flow of gasses through the chamber from the inlets 102A and 102B to the outlets 103. In some embodiments, the plasma chamber may be pressurized to a low pressure, e.g., between about 1 mtorr to 10 torr, for example.

The carrier 30 with the mounted wafer is placed on a chuck 50. The plasma may be generated by powering the top electrode electrical connection node 75. A RF generator, e.g., operating at 13.56 MHz, may be coupled to the top electrode electrical connection node 75 for powering the plasma in one embodiment.

In another embodiment, the chuck 50 may be powered, e.g., with RF power while the top electrode electrical connection node 75 may be grounded.

In another embodiment, a high density plasma may be used to etch the substrate 10, the etching process starting from the exposed back surface 12. Accordingly, a high density plasma etch tool, for example, an microwave generator plasma tool or alternatively an inductively coupled plasma tool may be used. The plasma may be generated by powering the top electrode electrical connection node 75 from about 100 W to about 2000 W, and about 850 W in one embodiment. Additionally remote plasma generated by a microwave plasma generation unit may be used in some embodiments.

In various embodiments, in a plasma etching system, a high electric field is applied between the top electrode 70 and the chuck 50, which ionizes some of the gas atoms within the plasma chamber 100 to form a plasma 90. A voltage bias is developed between the plasma 90 and the top electrode 70 and the chuck 50. The charged ions as well as neutral chemical radicals may be accelerated and directed towards the wafer mounted over the chuck 50 resulting in etching.

The etch rates are also dependent on the temperature of the wafer surface, which is adjusted by the underlying heater. Further, in a plasma etching process, the net etch rates are the superposition of the intrinsic plasma etch rates, which may be combination of chemical and/or physical etching, and the deposition rates of material deposited on the surface of the material being removed. For example, the plasma may deposit some of the atoms from the plasma or the top electrode 70. Alternatively, some of this deposition may also be re-deposition of material that is being removed. The deposition processes counteracts or act opposite to the etching processes. Accordingly, a plasma process may be switched from being an etching process to a deposition process by changing the plasma process conditions.

Importantly, the deposition rates and etching rates have different temperature dependence because of the different processes involved during deposition versus etching. In particular, deposition rates may be strongly non-linear. In other words, the deposition rate may vary non-linearly with a change in temperature. Because the net etching rate observed on the wafer depends on the deposition rates, the net etching rate also varies non-linearly with a change in temperature. Consequently, in various embodiments, a non-uniform plasma etching process is designed to eliminate the previously introduced thickness non-uniformities. The main contributor to the non-uniformity of the net etching rate is the strongly temperature dependent deposition process that is inherently part of the plasma process. Accordingly, the non-uniformity of the net etching rate can be adjusted by adjusting the deposition process relative to the etching process because of this strong temperature dependence.

Therefore, the inventors of this application have found that an accurate control of the temperature of the wafer surface results in an accurate control of the etching rate at the wafer surface. Accordingly, non-uniformity in etching across the wafer may be controlled by controlling the temperature locally, for example, by locally monitoring and adjusting the temperature of the wafer surface.

In some embodiments, the non-uniform plasma etching process may also be used to re-adjust the surface thickness non-uniformity to a different type of variation in some embodiments. For example, if a subsequent process is designed to remove material or deposit material at a non-uniform rate, then this preceding process may be used to balance the subsequent non-uniformity to be introduced.

Non-uniformities of the net etching rate may exhibit as a radial component due to the reactor geometry and a non-radial component due to process itself or may also be due to the reactor geometry. Embodiments of the present invention describe also reducing both the radial component and non-radial component of the net etching rate with the use of local heating techniques.

In various embodiments, radial non-uniformities, from the previous grinding step as well as the present plasma etching step, are controlled using a radial temperature control with the use of a multi-zone electrostatic chuck 50. Non-radial uniformities, from the previous grinding step as well as the present plasma etching step, are controlled using a local temperature control 60. However, in some embodiments, both non-radial and radial temperature control may be implemented within a heating element of the multi-zone electrostatic chuck 50.

Accordingly, in various embodiments, a thinning of wafer substrates using plasma thinning in the back-end (BE) is improved using both radial and non-radial non-uniformities thickness control.

In various embodiments, for plasma based precision thinning of wafer substrates, the plasma chemistry is made up of at least one feed gas to provide intrinsic etching of the substrate. Further, in one or more embodiments, at least one feed gas is used that results in a wafer surface temperature dependent deposition of material onto the substrate.

In case of etching silicon substrates, the intrinsic etch chemistries may be controlled using halide based etchants such as SF₆. The feed gases providing etch retarding deposition may be carbon based gases such as CH₄, C4F₈, and others, and/or silicon based sources such as SiF₄, SiCl₄, and others.

Precision thinning may be achieved by a combination of both radial and non-radial temperature control by a multi-zone electrostatic chuck 50 and a localized temperature control 60 respectively. In one embodiment, the localized temperature control 60 is provided by a plurality of localized/segmented heating units 61-66. The plurality of localized/segmented heating units 61-66 may comprise individual heating elements that can be adjusted individually so that a local variation in temperature may be obtained.

FIG. 4B illustrates a top sectional view of the heating unit within the electrostatic chuck in accordance with an embodiment of the present invention.

As illustrated in FIG. 4B, the chuck 50 may include a radial heating control unit comprising a plurality of radial heating elements 51, which may be individually controlled. The radial heating elements 51 may be adjusted to minimize radial variation in the deposition rates, which minimizes variation in radial etching rates.

FIG. 4C illustrates a top sectional view of the plurality of localized/segmented heating units in accordance with an embodiment of the present invention.

The plurality of localized/segmented heating units 60 such as heating units 61-66 may be individually controlled providing a non-radial control. In some embodiments, the radial heating elements 51 may be skipped since the plurality of localized/segmented heating units 60 may be able to provide localized (e.g., pixel like) control of the temperature at any point on the substrate 10.

In various embodiments, the plurality of localized/segmented heating units 60 (as well as the radial heating units in the chuck 50) may be configured to compensate to variations arising in the plasma process, plasma chamber effects, and others.

In various embodiments, a test wafer or a first wafer in a batch of wafers may be used as a monitor wafer. The thickness of the substrate 10 may be monitored on the test wafer and subsequent wafers may be processed differently by adjusting the heating elements described above.

In some embodiments, a dynamic control may be used to set the temperature of the individual heating elements. For example, in one embodiment, a temperature sensor may monitor the wafer surface temperatures on an on-going or periodic basis and adjust the individual heating elements based on the measured temperature values. Accordingly, a separate test wafer may not be needed to calibrate the process tool in this embodiment.

FIG. 4D illustrates a plurality of localized/segmented heating units in accordance with an embodiment of the present invention.

A plurality of localized/segmented heating units may be spatially located on a grid like array in various embodiments. As illustrated in FIG. 4D, in one embodiment, each of the plurality of localized/segmented heating units may include a heating unit HU60, which may be coupled independently so that the current through a particular heating unit HU60 may be adjusted. The size of the individual heating unit HU60 may be varied depending on the spatial area of the wafer to be heated.

In various embodiments, the heating mechanism may be selected by a person having ordinary skill in the art to be, for example, resistance based, induction based, lamp based, and others as well as combinations thereof. The terminals ends B1-B5 of the heating units HU60 may be coupled to a controller CTL10, which may change the current through one or more lines individually or in a sequence as an illustration. For example, after measuring a test wafer, the controller CTL10 may store an appropriate heating pattern to be applied to each heating unit HU60 so that non-radial non-uniformities are minimized. In some embodiments, the CTL10 may automatically determine the best heating pattern to be applied for minimizing temperature variations. In further embodiments, the CTL10 may select a heating profile that minimizes both radial and non-radial uniformities. In alternative embodiments, the best heating pattern may be selected dynamically during the heating process itself. For example, after heating the wafer using a first heating pattern applied to the plurality of heating units HU60, the temperature profile or heating pattern may be adjusted to obtain a more uniform distribution.

In one or more embodiments, the controller CTL10 may be designed to test a plurality of stored heating patterns, for example, predetermined heating patterns, and to select the heating pattern that provides the least variation in the measured wafer surface temperature or a measured thickness across the wafer.

In a further embodiment, a test wafer may be etched in the process chamber, and actual etch non-uniformities may be determined. The etch profile of the test wafer may be input into the controller CTL10, which may then back calculate the best temperature pattern that minimizes etch variations. The computed heating pattern may be applied to subsequent wafers that are processed in the process chamber. Thus, in various embodiments, across die variations may be minimized.

The controller CTL10 may be coupled to volatile and non-volatile memory for storing and retrieving information regarding the heating patterns being used, as well as other hardware as necessary.

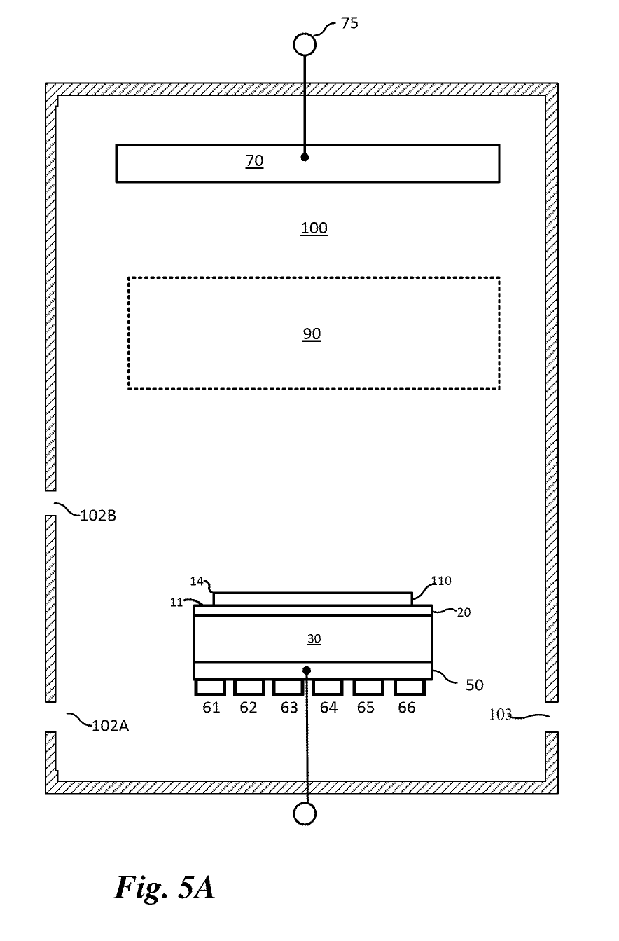

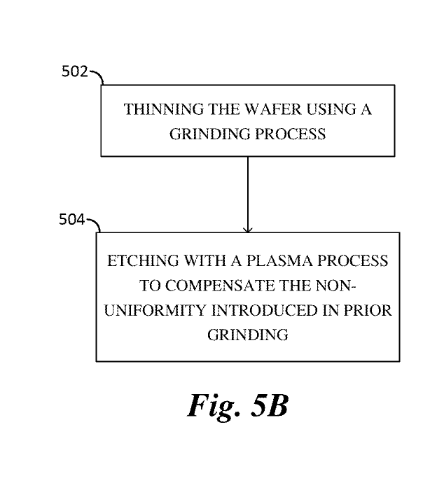

FIG. 5A illustrates the wafer at the end of the plasma etching process in accordance with embodiments of the present invention.

The thinned surface 110 at the end of the plasma process is illustrated in FIG. 5A. A smoothed surface 14 is exposed after the plasma etching process. Because of the use of the radial and non-radial temperature controls as described above, the smoothed surface 14 exhibits very less non-uniformity, relative to the surface of FIG. 3B. For example, the variation of the thickness of the substrate 110 at any point along the wafer is within 5% of the total average thickness, and within 1% of the total average thickness in one embodiment. Also, in another embodiment, the chuck 50 may be powered, e.g., with RF power while the top electrode electrical connection node 75 may be grounded.

FIG. 5B illustrates a process flow for forming a semiconductor device as described above in accordance with embodiments of the present invention.

Accordingly, as illustrated in FIG. 5B, in one or more embodiments, the method of thinning a wafer comprises thinning the wafer using a grinding process (box 502). The wafer after the grinding processing has a first non-uniformity in thickness. Using a plasma process, the thinned wafer is etched (box 504). The wafer after the etching processing has a second non-uniformity in thickness. The second non-uniformity is less than the first non-uniformity. For example, the variation in thickness after the grinding process is much larger than the variation in thickness after the etching process. In one or more embodiments, the standard variation of this variation is at least 10% lower.

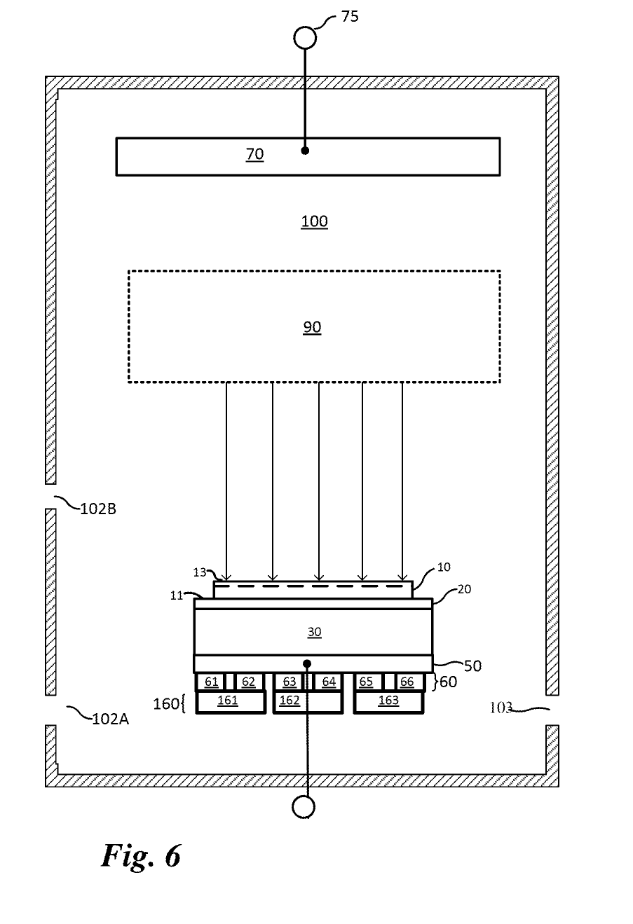

FIG. 6 illustrates a plasma etching process using an alternative design for the localized temperature control units in accordance with an embodiment of the present invention.

In this embodiment, a plurality of additional heating elements 160 is added below the plurality of localized/segmented heating units 60. The plurality of additional heating elements 160 may be shaped differently from the heating elements within the chuck 50 or the plurality of localized/segmented heating units 60 so as to provide a better control of the temperature profile at the surface of the substrate 10. In this embodiment as well, in a different embodiment, the chuck 50 may be powered, e.g., with RF power while the top electrode electrical connection node 75 may be grounded.

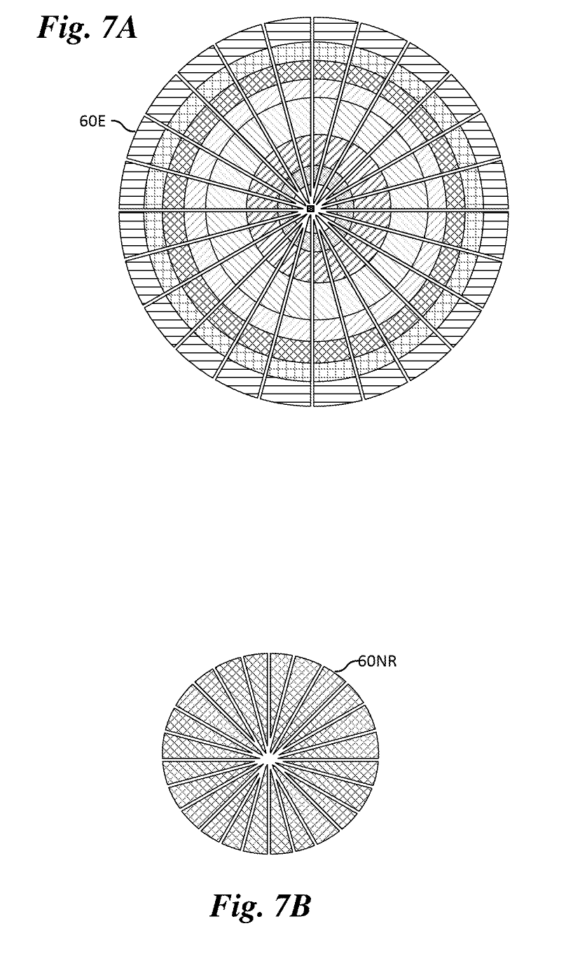

FIG. 7A illustrates a top sectional view of a heating unit comprising radial and non-radial heating elements in accordance with an embodiment of the present invention.

Referring to FIG. 7A, the heating units may include radial and non-radial heating elements 60E transposed together in some embodiments. Accordingly, each sectional portion comprises an individual heating unit so that both a radial and non-radial heating pattern may be superimposed and the wafer may be heated to control both radial and non-radial heating non-uniformities by adjusting the heat emanating from the radial and non-radial heating elements 60E.

FIG. 7B illustrates a top sectional view of a heating unit comprising non-radial heating elements in accordance with an alternative embodiment of the present invention.

In this embodiment, only non-radial heating elements 60NR are illustrated. For example, this embodiment may be combined together with a heating unit comprising radial elements such as, for example, illustrated in FIG. 4B. The non-radial heating elements 60NR are arranged in a circular pattern and comprise a shape similar to a section of a circle in one embodiment.

Embodiments of the present invention may also be applied to other plasma processes such as plasma enhanced chemical vapor deposition and sputtering or physical vapor deposition, and other deposition tools including chemical vapor deposition.

FIG. 8 illustrates a deposition system in accordance with an embodiment of the present invention.

In an exemplary deposition process, a sputter deposition process is described. In other embodiments, the deposition process may also be applied to a chemical vapor deposition process including a plasma enhanced chemical vapor deposition system.

In a sputter deposition system, an inert gas such as argon is input into the sputtering chamber 700 at a low pressure. A negative voltage is applied between the target electrode 770 and the bottom electrode 750 to create a plasma 790. The positive ions in the plasma 790 are accelerated to the target electrode 770 and release target atoms upon impact. The target atoms from the target electrode 770 are then deposited onto the exposed surface of the wafer 710 mounted over the bottom electrode 750.

In various embodiments, the temperature of the bottom electrode 750 and the wafer 710 are controlled by the heating elements comprising a non-radial heating element 760A (similar to the plurality of localized/segmented heating units described above) and a radial heating unit (as described above in various embodiments), for example, disposed within the chuck 750. Further, an additional heating unit 760B may be disposed under or above the non-radial heating element 760A. Accordingly, the film properties of the deposited film are controlled and adjusted by the temperature of the wafer 710 by the heating units having separate non-radial and radial temperature control.

Embodiments of the present invention may also be applied to RF sputter deposition in which high-frequency AC voltage is applied to the target electrode 770.

Embodiments of the present invention not only provide precision substrate thinning, but in or more embodiments, the mechanical stress introduced into the substrate during the preceding mechanical grinding process as well as other prior processes may be relieved during the plasma thinning process.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. For example, embodiments of the present invention described in FIGS. 1-8 may be combined together in alternative embodiments. It is therefore intended that the appended claims encompass any such modifications or embodiments.

What is claimed is:

1. A method of thinning a wafer, the method comprising:
thinning the wafer using a grinding process, the wafer after the grinding processing has a first non-uniformity in thickness; and
using a plasma process, etching the thinned wafer, the wafer after the etching processing has a second non-uniformity in thickness, wherein the second non-uniformity is less than the first non-uniformity.

2. The method of claim 1, wherein the first non-uniformity in thickness comprises a first non-radial component, wherein the second non-uniformity in thickness comprises a second non-radial component, and wherein the second non-radial component is less than the first non-radial component.

3. The method of claim 1, wherein the etching the thinned wafer comprises:
providing a plurality of heating elements of a heating unit disposed in a process chamber;
placing the wafer in the process chamber, wherein the wafer is mounted over the heating unit comprising the plurality of heating elements, wherein each of the plurality of heating elements is configured to be heated independently from the remaining of the plurality of heating elements;
after placing the wafer, heating each of the plurality of heating elements, wherein the heating is configured to reduce the first non-uniformity; and
processing the wafer in the process chamber.

4. The method of claim 3, wherein processing the wafer comprises exposing the wafer to a plasma.

5. The method of claim 3, wherein heating the wafer comprises adjusting a heating current of the plurality of heating elements based on a measured temperature variation.

6. The method of claim 5, wherein the measured temperature variation is measured on a prior wafer processed in the process chamber.

7. The method of claim 3, wherein heating each of the plurality of heating elements comprises simultaneously and independently heating each of the plurality of heating elements.

8. The method of claim 7, wherein each of the plurality of heating elements is electrically coupled to a controller configured to supply varying levels of current individually to each of the plurality of heating elements.

9. The method of claim 3, wherein the plurality of heating elements comprises a row of discrete heating elements extending from a first edge of the wafer to an opposite second edge of the wafer along a first direction.

10. The method of claim 9, wherein the plurality of heating elements comprises a column of discrete heating elements extending from a third edge of the wafer to an opposite fourth edge of the wafer along a second direction, wherein the second direction is perpendicular to the first direction.

11. The method of claim 3, wherein each of the plurality of heating elements comprises a resistive heating element.

12. A method of etching comprising:
mounting a substrate in a process chamber, wherein the substrate is mounted over a heating unit comprising a plurality of heating elements disposed in a plane parallel to the substrate;
heating each of the plurality of heating elements, wherein a level of heating of each of the plurality of heating elements is varied in a non-radial pattern for producing a non-radial heat distribution emanating from the plurality of heating elements; and
etching the substrate in the process chamber after the heating.

13. The method of claim 12, further comprising producing a corresponding non-radial heat distribution at a surface of the substrate exposed to the etching.

14. The method of claim 12, further comprising simultaneously supplying different current levels to each of the plurality of heating elements during the heating.

15. The method of claim 12, further comprising:
before the heating, measuring a surface temperature of the substrate; and
configuring the level of heating applied to each of the plurality of heating elements based on the measured surface temperature.

16. The method of claim 12, further comprising:
before the heating, heating a different substrate in the process chamber according a first heating pattern;
measuring a surface temperature of the different substrate;
applying a second heating pattern different from the first heating pattern, wherein the second heating pattern comprises a different non-radial heat distribution from the first heating pattern; and
heating the substrate using the second heating pattern.

17. The method of claim 12, wherein the plurality of heating elements comprises a row of discrete heating elements extending from a first edge of the substrate to an opposite second edge of the substrate along a first direction.

18. The method of claim 17, wherein the plurality of heating elements comprises a column of discrete heating elements extending from a third edge of the substrate to an opposite fourth edge of the substrate along a second direction, wherein the second direction is perpendicular to the first direction.

19. A method of thinning a wafer, the method comprising:
providing a wafer having a first non-radial non-uniformity in thickness; and
etching the wafer using a plasma process, the wafer having a second non-radial non-uniformity in thickness after the etching, wherein the second non-radial non-uniformity is less than the first non-radial uniformity, wherein a heating pattern for heating an exposed major surface of the wafer is computed to reduce the first non-radial non-uniformity to the second non-radial non-uniformity before the etching.

20. The method of claim 19, wherein the etching the thinned wafer comprises:
providing a plurality of heating elements of a heating unit disposed in a process chamber;
placing the wafer in the process chamber, wherein the wafer is mounted over the heating unit comprising the plurality of heating elements, wherein each of the plurality of heating elements is configured to be heated independently from the remaining of the plurality of heating elements;
after placing the wafer, heating each of the plurality of heating elements, wherein the heating is configured to reduce the first non-radial non-uniformity; and
processing the wafer in the process chamber.

21. The method of claim 20, wherein processing the wafer comprises exposing the wafer to a plasma.

22. The method of claim 20, wherein heating the wafer comprises adjusting a heating current of the plurality of heating elements based on a measured temperature variation.

23. The method of claim 22, wherein the measured temperature variation is measured on a prior wafer processed in the process chamber.

24. The method of claim 20, wherein heating each of the plurality of heating elements comprises simultaneously and independently heating each of the plurality of heating elements.

25. The method of claim 24, wherein each of the plurality of heating elements is electrically coupled to a controller configured to supply varying levels of current individually to each of the plurality of heating elements.

26. The method of claim 20, wherein the plurality of heating elements comprises a row of discrete heating elements extending from a first edge of the wafer to an opposite second edge of the wafer along a first direction.

27. The method of claim 26, wherein the plurality of heating elements comprises a column of discrete heating elements extending from a third edge of the wafer to an opposite fourth edge of the wafer along a second direction, wherein the second direction is perpendicular to the first direction.

28. A process tool comprising:
a plasma chamber;
a chuck disposed in the plasma chamber, the chuck being configured to hold a thinned wafer during processing, the thinned wafer having a first non-uniformity in thickness from a prior grinding process; and
a heating unit comprising a plurality of heating elements, wherein each of the heating elements is configured to be heated independently from the remaining of the plurality of heating elements, wherein the process tool is configured to etch the thinned wafer, wherein the thinned wafer after the etching has a second non-uniformity in thickness, wherein the second non-uniformity is less than the first non-uniformity.

29. The process tool of claim 28, wherein the plurality of heating elements comprises a row of discrete heating elements extending from a first edge of the thinned wafer to an opposite second edge of the thinned wafer along a first direction.

30. The process tool of claim 29, wherein the plurality of heating elements comprises a column of discrete heating elements extending from a third edge of the thinned wafer to an opposite fourth edge of the thinned wafer along a second direction, wherein the second direction is perpendicular to the first direction.

31. The process tool of claim 28, wherein the process tool comprises a temperature tool to measure a surface temperature of the thinned wafer.

32. The process tool of claim 28, further comprising a controller configured to provide current to each of the plurality of heating elements, wherein the controller is configured to supply a different current simultaneously to each of the plurality of heating elements.

33. The process tool of claim 28, wherein each of the plurality of heating elements comprises a resistive heating element.
